(19) United States
(12) Patent Application Publication
(10) Pub. No.: US 2026/0107415 A1
(43) Pub. Date: Apr. 16, 2026

(54) LIDLESS COLD PLATE ASSEMBLY

(71) Applicant: Nvidia Corporation, Santa Clara, CA (US)

(72) Inventors: John Franz, Tomball, TX (US); Tahir Cader, Spokane Valley, WA (US); David Brien Haley, Beaverton, OR (US); Matthew Richard Slaby, Beaverton, OR (US)

(21) Appl. No.: 18/913,442

(22) Filed: Oct. 11, 2024

(51) Int. Cl. H05K 7/20

(52) U.S. Cl. CPC H05K 7/20272; H05K 7/20254

(57) ABSTRACT

Systems and methods herein are for a lidless cold plate assembly having a lidless cold plate that may be configured for association with an underlying component. A distribution manifold may be included and may have central fasteners for fastening to the lidless cold plate. A stiffener frame with perimeter fasteners may enabling fastening of the stiffener frame to the lidless cold plate. This may be so that the central fasteners are closer to a center of the lidless cold plate assembly relative to perimeter fasteners.

### TECHNICAL FIELD

At least one embodiment pertains to cooling in computer environments such as datacenters.

### BACKGROUND

Computer environments such as datacenters may be subject to liquid cooling. Liquid cooling may use cold plates to interface with computing features of a computer module. However, package sizes of such cold plates have been increasing and may be subject to limitations in dimensions relative to a computer module. The increase in package sizes may cause issues, such as, warping, in certain applications. Further, warping in a cold plate may result in gaps between a cold plate and an underlying computing features or component. Consequently, the gaps may cause an uneven thermal connection between the cold plate and the computing feature at any interface therebetween. Further, there may be stresses on brittle silicon and on solder joints of a ball grid array (BGA) of a circuit board supporting such solder joints. The stresses may be from handling of the cold plate and its attachment forces and during servicing events associated with lidless or exposed die packages. In addition, a lidless cold plate may be subject to issue of deflection under pressure from fluid flow.

### BRIEF DESCRIPTION OF DRAWINGS

FIG. 1 is an illustration of a datacenter subject to a lidless cold plate assembly, in at least one embodiment;

FIG. 2A is an illustration of computer module aspects of a lidless cold plate assembly, in at least one embodiment;

FIG. 2B is an illustration of certain aspects of a lidless cold plate assembly, in at least one embodiment;

FIG. 2C is an illustration of further aspects of a lidless cold plate assembly, in at least one embodiment;

FIG. 2D is an illustration of detailed aspects of a lidless cold plate assembly, in at least one embodiment;

FIG. 2E is an illustration of a lidless cold plate assembly having a lidless cold plate, a distribution manifold, and a stiffener frame, in at least one embodiment;

FIG. 2F is an illustration of aspects associated with reduced deflection in a lidless cold plate assembly from using internal screw retention, described as central fasteners herein, in at least one embodiment;

FIG. 3A is an illustration of sealing and guidance aspects of a lidless cold plate assembly, in at least one embodiment;

FIG. 3B is a detailed illustration of certain guidance aspects of a lidless cold plate assembly, in at least one embodiment;

FIG. 4 illustrates rack aspects in a system subject to a lidless cold plate assembly, according to at least one embodiment;

FIG. 5A illustrates a process flow for a system having at least one lidless cold plate assembly, in at least one embodiment;

FIG. 5B illustrates yet another process flow for a system having at least one lidless cold plate assembly, in at least one embodiment; and

FIG. 6 illustrates an example datacenter, in which at least one embodiment from FIGS. 1-5B may be used.

### DETAILED DESCRIPTION

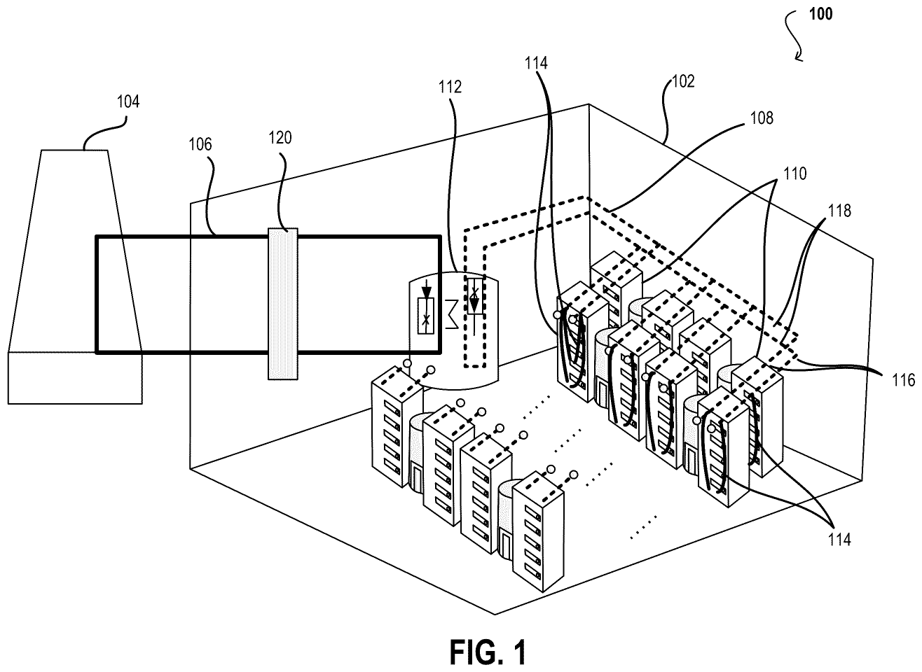

FIG. 1 is an illustration of a system subject to a lidless cold plate assembly, in at least one embodiment. The lidless cold plate assembly includes a distribution manifold with central fasteners and a stiffener frame with perimeter fasteners. To address limitations in liquid cooling in a datacenter, provided herein is a system and method of a lidless cold plate assembly that is subject to stiffening and anti-deflection in its heat removal microchannels. The stiffening and anti-deflection may be based in part on a combination of a distribution manifold with central fasteners to a lidless cold plate and a stiffener frame with perimeter fasteners to the lidless cold plate. The central fasteners may be located closer to a center of the lidless cold plate assembly relative to the perimeter fasteners. While cold plates may be associated to a top of computing feature, such association may require an Integrated Heat Spreader (IHS). For instance, a solid block of material may need to be bonded to silicon of the computing feature to provide a lidded cold plate. However, exposing silicon of a computing feature so that direct connection may exist to a cold plate and which structure may be subject to a perimeter stiffener frame (such as, a metal frame) provides an assembly that may be referred to herein as a lidless cold plate. This is at least partly because the silicon of the underlying computing feature may be visible or accessible directly to heat removal microchannels of the lidless cold plate.

The lidless cold plate may include the heat removal microchannels and which may be exposed or not subject to a lid with respect to the lidless cold plate itself. Instead, the heat removal microchannels may be subject to first sealing at a perimeter thereof using a first O-ring seal between the lidless cold plate and a perimeter stiffener frame and may be subject to second sealing at a center thereof using a bypass seal between the lidless cold plate and the distribution manifold. The distribution manifold may include distribution channels that may also be sealed at its perimeters with a second O-ring seal between the distribution manifold and a manifold lid and may be sealed at its center by a manifold port plate. Further, all such seals may be elastomeric seals.

As such, the lidless cold plate assembly incorporates a lidless cold plate at least by virtue of a cold plate not having a lid with respect itself and that may, instead, be subject to a bypass seal. The lidless cold plate assembly may use the distribution manifold fastened with central fasteners to the lidless cold plate to prevent deflection in the heat removal microchannels of the cold plate and may use the perimeter stiffener frame fastened with perimeter fasteners to the lidless cold plate to provide stiffening for co-planarity of the lidless cold plate and the underlying component.

The lidless cold plate assembly herein can address liquid cooling of computing features such as, processors that may include central processing units (CPUs), graphics processing units (GPUs), data processing units (DPUs), application-specific integrated circuits (ASICs), memories, and switches or regulators. For instance, GPUs may be provided as a GPU package and may be subject to large power consumption requirements and a large layout size. Such a GPU package may need more memory and may incorporate an increase in their BGA to support power delivery and signal throughput. As package size increases for computing features, the issues of warping, which may cause the aforementioned gaps and uneven thermal connection, also increases, along with the other issues described. However, in the lidless cold plate assembly herein, a thermal interface layer may not be used, which can improve performance of the computing features while also reducing warping risks as a size of the package increases.

In addition, warping may be also a result of internal fluid pressure used with a cold plate and the liquid cooling provided thereto. However, the lidless cold plate assembly herein incorporates assembly and service improvements at least by a primary attribute of separating a cold plate into two distinct sections to enable ideal silicon chip manufacturing processes. For instance, a bottom half of the lidless cold plate assembly may be associated with a stiffener frame and the lidless cold plate with the heat removal microchannels, while a top half may be associated with the distribution manifold and other assembly aspects of a lidless cold plate assembly. Further, the reference to halves is only not as to equal separation of the lidless cold plate assembly, but is in reference to lidless cold plate assembly having different portions that may be in at least two functionally different portions of the lidless cold plate assembly. In addition, the separation maintains the cooling aspects by allowing a media (such as, a coolant) to reach the heat removal microchannels from an external cooling loop of a system tray, computer module, or other mounting hardware.

Therefore, the stiffener frame at a perimeter of the lidless cold plate assembly incorporates a structural integrity into the lidless cold plate assembly that can mechanically connect to a cold plate. Further, the lidless cold plate having the heat removal microchannels as separate features of the lidless cold plate assembly, can be associated with the distribution manifold in addition to the stiffener frame to add further to the structural integrity. In addition, these separations to provide the lidless cold plate assembly incorporates design for manufacturing by the optimized cold plate having the heat removal microchannels as a distinct feature for manufacturing therein.

The design for manufacturing aspects, in one instance, allows for different material options, if needed, for each part of the lidless cold plate assembly to achieve optimal thermal performance and strength. The lidless cold plate assembly allows for manufacturing flexibility, while also offering traditionally bonded silicon device-type capabilities in terms of thermal and flatness capabilities. The lidless cold plate assembly incorporates a screw-down attachment of the top half to the bottom half with different fasteners at different perimeter locations. For instance, internal screw retention using a set of fasteners may be provided in one central location to combat fluid pressure-based deformation. This can address internal fluid pressure deformation that may be caused when external forces on a cold plate retention are not balanced. The lidless cold plate assembly herein may be subject to pressures of 100 pounds per square inch (psi) of internal fluid pressure and 30 psi of external compression forces. These pressures and forces may, otherwise, result in stress on silicon components and integrity of the thermal interface bond. At least the internal screw retention, described as central fasteners herein that may be between the distribution manifold and the lidless cold plate, can also link to distribution channels of the distribution manifold to reduce deflection that may otherwise occur in a lidless cold plate, by more than 90%. Such reduction can improve thermal joint quality and reduction in silicon stresses.

FIG. 1 is a block diagram of an example datacenter 100 having a cooling system subject to improvements described in at least one embodiment. The datacenter 100 may be subject to a lidless cold plate assembly having a distribution manifold with central fasteners and a stiffener frame with perimeter fasteners, in at least one embodiment. The datacenter 100 may be one or more rooms 102 having racks 110 and auxiliary equipment to house one or more servers on one or more server trays having circuit boards therein, which may be altogether referred to herein as computer modules. The datacenter 100 may be supported by a cooling tower 104 located external to the datacenter 100. The cooling tower 104 may dissipate heat from within the datacenter 100 by acting on a primary cooling loop 106. Further, a cooling distribution unit (CDU) 112 may be used between the primary cooling loop 106 and a secondary cooling loop 108 to enable extraction of the heat from the secondary cooling loop 108 to the primary cooling loop 106. The secondary cooling loop 108 can access various plumbing all the way into the server tray as required, in an aspect.

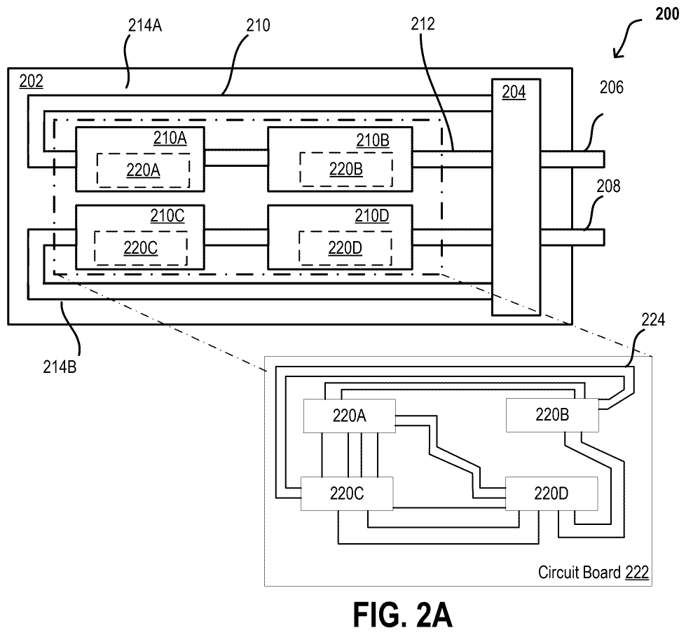

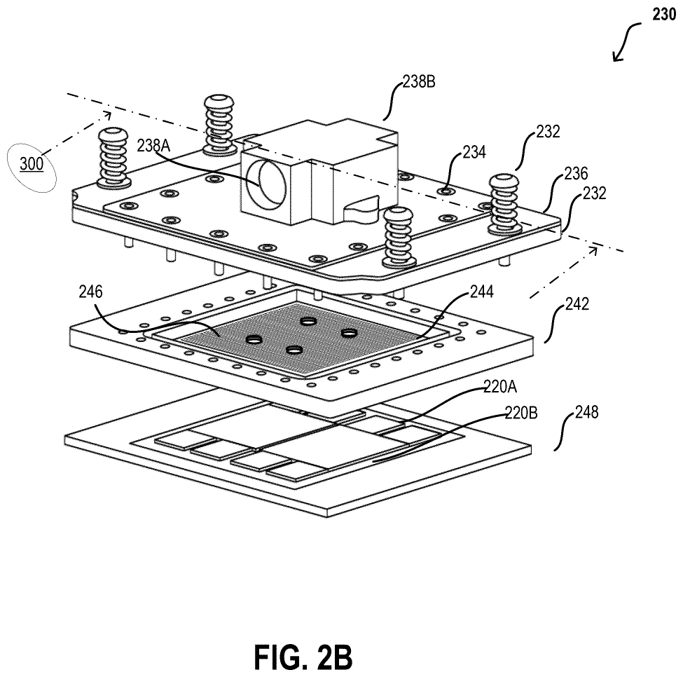

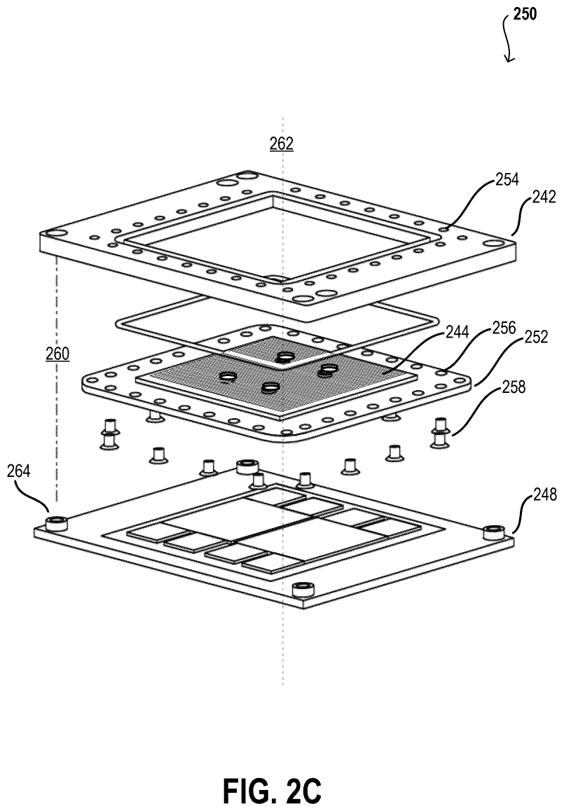

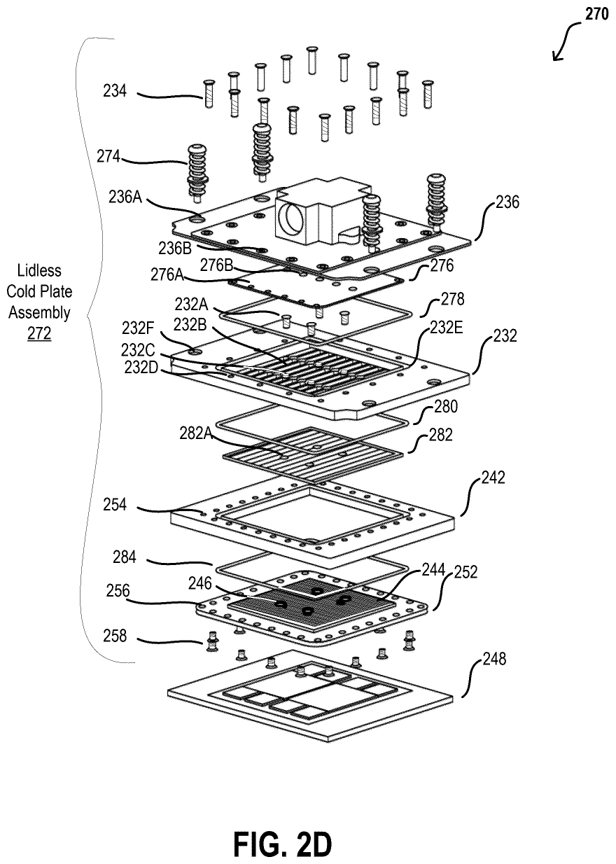

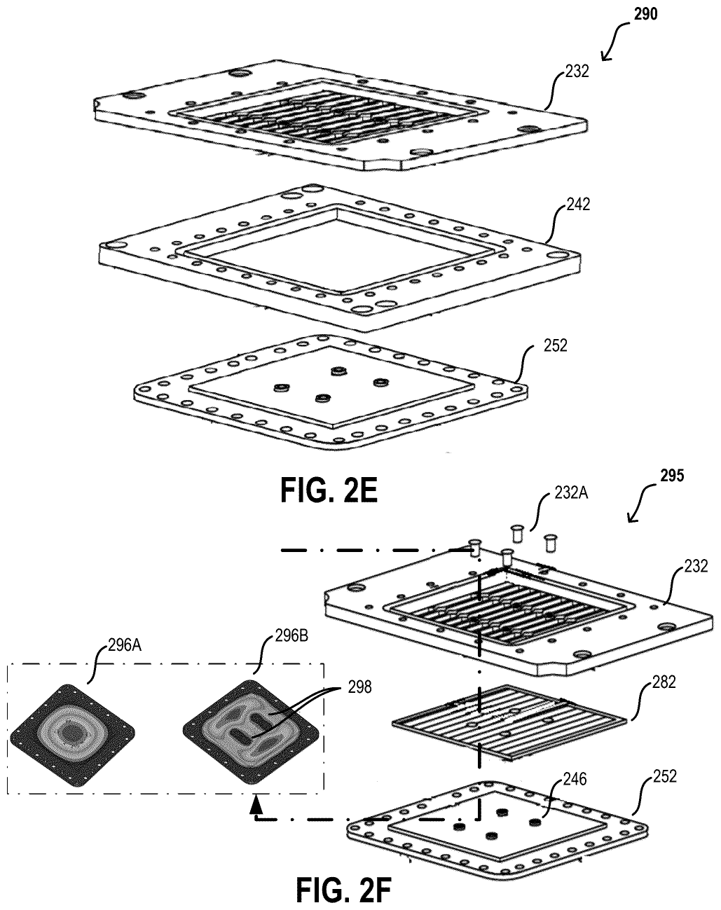

The primary and secondary cooling loops 106, 108 are illustrated as line drawings, but a person of ordinary skill would recognize that one or more plumbing features may be used. In an instance, flexible polyvinyl chloride (PVC) pipes may be used along with associated plumbing to move the media along in each of the primary and secondary cooling loops 106, 108. One or more pumps, in at least one embodiment, may be used to maintain pressure differences within the primary and secondary cooling loops 106, 108 to enable the movement of a media (such as, a primary media or a secondary media that may be a coolant or refrigerant) according to temperature sensors in various locations, including in the room, in one or more racks 110, and/or in server boxes or server trays within the racks 110. As used herein, at least the secondary cooling loop 108, which is associated with a primary cooling loop 106, may be configured to cool computing features of the computer module using a lidless cold plate assembly having a distribution manifold with central fasteners and a stiffener frame with perimeter fasteners, as detailed further in one or more of FIGS. 2A-6 herein.

In at least one embodiment, a secondary media in a secondary cooling loop 108 have an inlet temperate of above 0 degrees centigrade (° C) but less than 40°° C., and may exit with a temperature of about 60° C. In one example, a primary media in the primary cooling loop 106 may be used to cool the secondary media in the secondary cooling loop 108. The primary media and the secondary media may be at least water and an additive, for instance, glycol or propylene glycol. In operation, each of the primary and the secondary cooling loops 106, 108 have their own media. In an aspect, the media in the secondary cooling loops may be proprietary to requirements of the components in the server tray or racks 110.

The CDU 112 may be capable of sophisticated control of the primary and the secondary media, independently or concurrently, in the primary and the secondary cooling loops 106, 108. For instance, the CDU may be adapted to control the flow rate of a secondary media of the secondary cooling loop 108 so that the secondary media may be appropriately distributed to extract heat generated within the racks 110. Further, more flexible tubing 114 is provided from the secondary cooling loop 108, relative to the primary cooling loop, to allow entry to each computer module and to provide secondary media to the computing features therein. In the present disclosure, the computing features may be used interchangeably to refer to the heat-generating components that benefit from the present datacenter cooling system.

The tubing 118 illustrated in FIG. 1 and that may form part of the secondary cooling loop 108 may be referred to as room manifolds. Separately, additional tubing 116 extending from such tubing 118 may also be part of the secondary cooling loop 108 but may be referred to as row manifolds. Still further, the tubing 114 illustrated in FIG. 1 may enter the racks as part of the secondary cooling loop 108, but may be referred to as rack cooling manifold. Further, the row manifolds 116 may extend to all racks along a row in the datacenter 100. The plumbing of the secondary cooling loop 108, including the manifolds or tubings 118, 116, and 114 may be improved by at least one embodiment of the present disclosure. An optional chiller 120 may be provided in the primary cooling loop within datacenter 102 to support cooling before the cooling tower. To the extent additional loops exist in the primary control loop, a person of ordinary skill would recognize reading the present disclosure that the additional loops provide cooling external to the rack and external to the secondary cooling loop; and may be taken together with the primary cooling loop for this disclosure.

In at least one embodiment, in operation, heat generated within server trays of the racks 110 may be transferred from at least one cold plate to a media exiting the racks 110 via flexible tubing of the row manifold 114 of the second cooling loop 108. Pertinently, secondary media (in the secondary cooling loop 108) from the CDU 112, for cooling the racks 110, moves towards the racks 110. The secondary media from the CDU 112 passes from on one side of the room manifold having tubing 118, to one side of the rack 110 via row manifold 116, and through one side of the server tray via provided tubing 114. Spent secondary media (or exiting secondary media carrying the heat from the computing features) may exit out of another side of the server tray (such as, enters left side of the rack and exits right side of the rack for the server tray after looping through the server tray or through components on the server tray). The spent secondary media that exits the server tray or the rack 110 comes out of different side (such as exiting side) of tubing 114 and moves to a parallel, but also exiting side of the row manifold 116. From the row manifold 116, the spent secondary media may move in a parallel portion of the room manifold 118 going in the opposite direction than the incoming secondary media (which may also be the renewed secondary media), and towards the CDU 112. Further, the spent secondary media may have an exit temperature of above 0° C. and may specifically be in the range of 40-60° C.

In at least one embodiment, the spent secondary media may exchange its heat with a primary media in the primary cooling loop 106 via the CDU 112. The spent secondary media may be renewed (such as relatively cooled when compared to the temperature at the spent second coolant stage) and ready to be cycled back to through the second cooling loop 108 to the computing features or components. Various flow and temperature control features in the CDU 112 enable control of the heat exchanged from the spent secondary media or the flow of the secondary media in and out of the CDU 112. CDU 112 is also able to control a flow of the primary media in primary cooling loop 106.

FIG. 2A is an illustration of computer module aspects 200 of a lidless cold plate assembly, in at least one embodiment. The aspects 200 may include server-level features and may include a computer module 202 having at least one server manifold 204 to allow entry and egress of a cooling media of a secondary cooling loop 108, from a rack 110. However, the server manifold 204 may include separate channels for inlet and for exit of media of the secondary cooling loop 108, which is illustrated as an extension from the rack to be secondary cooling loops 214A, 214B, within the computer module.

The secondary media may enter from a rack manifold, via inlet pipe 206 and may exit via outlet pipe 208. The secondary media, on the server side may travel via inlet line 210, through one or more cold plates 210A, 210B, and via outlet line 212 to the manifold 204. This represents at least one or multiple secondary cooling loops 214A, 214B within the server tray or box 202. These multiple secondary cooling loops 214A, 214B may be an extension of the secondary cooling loop 108 interfacing with the primary cooling loop 106 as they provide the same or substantially the same secondary media from the secondary cooling loop 108 to the cold plates 210A-210D. In at least one embodiment, the cold plates 210A-210D are associated with at least one computing component or feature 220A-220D. In addition, while illustrated as different cold plates, the illustrated cold plates 210A-210D may be part of a large single cold plate structure have integrated contact points that are specifically over the underlying computing features 220A-220D. A computing feature 220A-220D may include processors, memories, and switches or regulators. In one example, the processors may include graphics processing units (GPUs), central processing units (CPUs), data processing units (DPUs), and ASICs.

In at least one embodiment, even though illustrated as having one inlet and one outlet or exit for inlet line 210 and for outlet line 212, there may be multiple intermediate lines, such as flexible pipes associating the cold plate with the respective inlet line 210 and outlet line 212. In at least one embodiment, the intermediate lines directly couple the cold plate to the manifold 204 are provided inlet and outlets for such connections. In at least one embodiment, media adapters are provided to enable such coupling. In at least one embodiment, the media adapters are sized to the inlet and outlet provisions in the cold plate and the manifold 204.

FIG. 2A also illustrates that computer module aspects 200 may include a circuit board 222 having interconnect features 224 on a first side (top side, as illustrated) and on a second side (bottom side, similar features as the top side illustrated or soldered features relative to the top side). The interconnect features 224 may couple one or more of the computing features 220A-220D together. The interconnect features 224 may include copper traces, plated and non-plated through-holes, solder points, transmission lines, and electrically-insulating circuit board material over which such copper traces and solder points may lie.

In at least one implementation, a secondary cooling loop 108; 214A; 214B may be used to capture a largest portion of heat generated within the system, while targeting the computing features 220A-220D. For instance, it is possible to capture ambient heat that may be other than the targeted computing features 220A-220D. Therefore, it is possible to capture about 80-90% of heat generated from a computer module or a rack by one or more of the secondary cooling loops 108; 214A; 214B. This is even though the secondary cooling loop 108; 214A; 214B may operate at temperatures that are greater than 0° C. and even though the secondary cooling loop 108; 214A; 214B may operate using a water-based media. Any or all of the illustrated cold plates 210A-210D may be individual lidless cold plate assemblies.

FIG. 2B is an illustration of certain aspects 230 of a lidless cold plate assembly, in at least one embodiment. Pertinently, the aspects 230 in FIG. 2B are to broad features of a top half of a lidless cold plate assembly and also to broad features of a bottom half of the lidless cold plate assembly, whereas aspects 260 in FIG. 2C are to detailed features of a bottom half of the lidless cold plate assembly. As illustrated, the top half may be associated with the distribution manifold 232. The distribution manifold 232 may be associated with a manifold lid 236 that is fastened to the distribution manifold 232 using seal fasteners 234. In at least one embodiment, the seal fasteners 234 may be allowed to extend from the distribution lid 236, through the distribution manifold 232 and into the stiffener frame 242. Therefore, some of the perimeter apertures 254 may be used for perimeter fasteners 258 from the lidless cold plate 252 and some of the perimeter apertures 254 may be used for the seal fasteners 234. For example, there may be alternate ones of the perimeter apertures 254 used for the perimeter fasteners 258 and the seal fasteners 234.

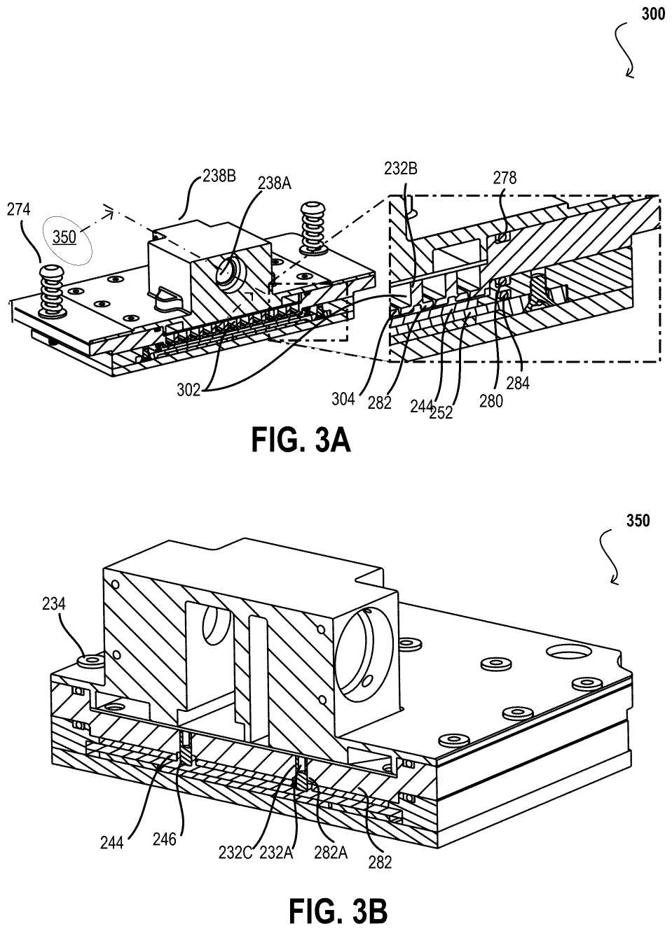

A manifold port plate, detailed further in FIG. 2D, may be provided between the manifold lid 236 and the distribution manifold 232 to guide media, such as a fluid, from a fluid inlet 238A of the manifold lid 236, through one or more ports of the manifold port plate and to distribution channels, detailed further in at least FIGS. 3A, 3B. The distribution channels allow the fluid to reach heat removal microchannels of the lidless cold plate. The media may exit from a fluid exit 238B of the manifold lid 236.

FIG. 2B illustrates that a stiffener frame 242 at a perimeter of the lidless cold plate assembly to incorporate a structural integrity into the lidless cold plate assembly that can mechanically connect to a lidless cold plate that is under the stiffener frame 242 and detailed further in at least FIGS. 2C to 3 herein. In addition, the lidless cold plate may include heat removal microchannels 244 as separate features of the lidless cold plate assembly and that can be associated with the distribution manifold 232 via central fasteners, detailed further in at least FIG. 2D. The central fasteners may be through central apertures 246 that may be screw or threaded holes of the lidless cold plate. This, in addition to the lidless cold plate being associated with the stiffener frame 242, further adds to the structural integrity of the lidless cold plate assembly. Further, the stiffener frame 242 may be associated with a substrate 248 by a bonding or a fixture thereto. The substrate 248 may be a circuit board with one or more computing features 220A, 220B thereon.

FIG. 2C is an illustration of further aspects 250 of a lidless cold plate assembly, in at least one embodiment. The system of a lidless cold plate assembly may include the lidless cold plate 252 that may be configured for association with an underlying component, such as a computing feature 220A-220D or a substrate 248 having the computing future 220A-220D thereon. The system may include the distribution manifold 232 with central fasteners to the central apertures 246 of the lidless cold plate 252. The central apertures 246 are illustrated through heat removal microchannels 244 of the lidless cold plate 252. As readily apparent, silicon of a computing feature 220A-220D may be exposed so that direct connection may exist to the lidless cold plate 252. The direct connection is because the silicon of the underlying computing feature 220A-220D may be visible or accessible directly to heat removal microchannels of the lidless cold plate. Further, there is no lid of the lidless cold plate 252 itself.

FIG. 2C also illustrates that the stiffener frame 242 may include perimeter apertures 254 for perimeter fasteners 258 to associate to aligned cold plate perimeter apertures 256 of the lidless cold plate 252. As apparent from FIG. 2C, the central apertures are closer to a center (illustrated via central axis 262) of the lidless cold plate assembly, relative to perimeter apertures 254. As a result, the central fasteners, described in at least FIGS. 3A, 3B, are closer to a center of the lidless cold plate assembly relative to perimeter fasteners 258. FIG. 2C also illustrates that the substrate 248 may be associated with the stiffener frame 242 by a bonding or fixture 260. When a fixture is used, the association between the substrate 248 and the stiffener frame 242 may be provided using substrate apertures 264 that may be threaded or screwed apertures.

FIG. 2D is an illustration of detailed aspects 270 of a lidless cold plate assembly 272, in at least one embodiment. The detailed aspects 270 may include one or more of the aspects 200, 230, 250 in FIGS. 2A-2C herein. For instance, the system of a lidless cold plate assembly 272 illustrated in the detailed aspects 270 may include a lidless cold plate 252 that may be configured for association with an underlying component 248. The system may include a distribution manifold 232 with central fasteners 232A to the lidless cold plate 252. For instance, central apertures 232C of the distribution manifold 232 may accept the central fasteners 232A as threaded or pass-through and to couple, via seal apertures 282A of a bypass seal 282, to the cold plate central apertures 246 of the lidless cold plate 252.

The system may include a stiffener frame 242 with perimeter fasteners 258 that may be provided from below, relative to the central fasteners 232A. The perimeter fasteners 258 are to fasten the stiffener frame 242to the lidless cold plate 252, via the cold plate perimeter apertures 256. The central fasteners 232A are closer to a center (illustrated via central axis 262) of the lidless cold plate assembly 272 relative to perimeter fasteners 258.

The system of the lidless cold plate assembly 272 may include the exposed heat removal microchannels 244. Further, the bypass seal 282 may be provided between the lidless cold plate 252 and the distribution manifold 232 in a manner to overlay the lidless cold plate 252. The bypass seal 282 may be held in place, in part by the central fasteners 232A and can maintain media, such as fluid, for cooling within the heat removal microchannels 244 without a lid that is provided to the lidless cold plate 252.

The system of the lidless cold plate assembly 272 may include a first O-ring seal 284 that may be between the stiffener frame 242 and the lidless cold plate 252. A second O-ring seal 278 may be provided in the system of the lidless cold plate assembly 272 to be between a distribution manifold 232 and a manifold lid 236 that is overlying distribution channels 232B of the distribution manifold 232. Further, FIG. 2D illustrates that the distribution manifold 232 may include an O-ring channel 232E for the second O-ring seal 278 to sit at least partly within therein and to seal between a top of the distribution channels 232B and an outside circumference of the distribution manifold 232. A third O-ring seal 280 may be provided in the system of the lidless cold plate assembly 272 to be between a distribution manifold 232 and a stiffener frame 242 that is overlying distribution channels 232B of the distribution manifold 232. Like in the case of the second O-ring seal, the third O-ring seal 280 may be within an O-ring channel of the stiffener frame 242 so that the third O-ring 280 can sit at least partly within the stiffener frame 242 and can seal between a bottom of the distribution channels 232B and an outside circumference of the distribution manifold 232.

The system of the lidless cold plate assembly 272 may include the distribution manifold 232 having the distribution channels 232B in a manner to allow media to pass therethrough and even through the bypass seal 282 to reach the heat removal microchannels 244 of the lidless cold plate 252. The manifold lid 236 may be fastened to the distribution manifold 232 using provided seal fasteners 234 through manifold lid apertures 236B of manifold lid 236 and through distribution manifold apertures 232D of the distribution manifold 232. A manifold port plate 276 may be provided between the manifold lid 236 and the distribution manifold 232 to guide fluid from a fluid inlet 238A of the manifold lid 236, through one or more ports 276B of the manifold port plate 276, to the distribution channels 232B. The distribution channels 232B can allow the fluid to reach the heat removal microchannels 244 of the lidless cold plate 252. In at least one embodiment, the manifold lid 236 may be fastened to the distribution manifold 232 using provided the seal fasteners 234 that are also through manifold port plate apertures 276A of the manifold port plate 276.

The system of the lidless cold plate assembly 272 may include the seal fasteners 234 to enable the manifold lid 236 to be fastened to the distribution manifold 232 at locations (such as the provided distribution manifold apertures 232D) that are around a first perimeter in relation to the distribution channels 232B that are inside the first perimeter. Separately, load fasteners 274 may be provided through different apertures 236A, 232F of at least the manifold lid 236 and of the distribution manifold 232 to enable a predetermined loading between the manifold lid 236 and the distribution manifold 232 at a second perimeter that is further away from a center of the lidless cold plate assembly 272 than the first perimeter having the distribution manifold apertures 232D. Therefore, the dimensions of one or more of the manifold lid 236 and the distribution manifold 232 may be more than the dimensions of one or more of the stiffener frame 242, the lidless cold plate 252, and the underlying component 248.

The system of the lidless cold plate assembly 272 may include the central fasteners 232A provided from above the lidless cold plate assembly, whereas the perimeter fasteners 258 for the stiffener frame and the lidless cold plate 252 may be provided from below the lidless cold plate assembly. The system of the lidless cold plate assembly 272 may include a profile or feature associated with one or more of a location of the central fasteners 232A or a loading on the central fasteners 232A. The profile or feature may include the central apertures 232C of the distribution manifold 232 and the cold plate central apertures 246 of the lidless cold plate 252, which may be predetermined, as to location and dimensions, based in part on a pressure of fluid to be handled in the lidless cold plate assembly 272 and an anti-deflection measure, in the heat removal microchannels 244, to be achieved under the pressure of the fluid. In one example, the anti-deflection measure may be based in part on a load required to counteract a change in a shape, geometry, or material deformation property of the heat removal microchannels.

The system of the lidless cold plate assembly 272 may be such that a profile or feature associated with one or more of a location of the perimeter fasteners 258, a loading on the perimeter fasteners 258, or a dimension of the stiffener frame 242 may be predetermined based in part on a dimension of the underlying component 248 and a stiffening measure to be imparted to the lidless cold plate 252. The stiffening measure may incorporate a predetermined stress at a center intended for the cold plate assembly, while also incorporating any axial forces along the perimeter of the stiffener frame.

Therefore, in at least one embodiment, a lidless cold plate assembly 272 may include a lidless cold plate 252, a distribution manifold 232 with central fasteners 232A to the lidless cold plate 252, and a stiffener frame 242 with perimeter fasteners 258 to the lidless cold plate 252.

The central fasteners 232A are closer to a center, provided by the central axis 262, of the lidless cold plate assembly 272 relative to perimeter fasteners 258. The lidless cold plate assembly 272 may also the exposed heat removal microchannels 244 and a bypass seal 282 that is between the lidless cold plate 252 and the distribution manifold 232 and that is overlying the lidless cold plate 252. The bypass seal 282 may be held in place, in part by the central fasteners 232A and can maintain fluid for cooling within the heat removal microchannels 244.

The lidless cold plate assembly 272 may also include a first O-ring seal 284 that is between the stiffener frame 242 and the lidless cold plate 252, and may include a second O-ring seal 278 that is between a distribution manifold 232 and a manifold lid 236 that is overlying distribution channels 232B of the distribution manifold 232. The lidless cold plate assembly 272 may also include the distribution channels 232B in the distribution manifold 232 in a manner that allows the manifold lid 236 to be fastened to the distribution manifold 232 with the second O-ring seal 278 therebetween to keep media in the distribution channels 232B.

The lidless cold plate assembly 272 may also include the manifold port plate 276 that is between the manifold lid 236 and the distribution manifold 232 to guide fluid from a fluid inlet 238A of the manifold lid and to a fluid exit 238B of the manifold lid. The guidance may be through one or more ports 276B of the manifold port plate 276. The guidance may be to the distribution channels 232B. The distribution channels 232B can allow the fluid to reach the heat removal microchannels 244 of the lidless cold plate 252, which is detailed further with respect to FIGS. 3A, 3B.

The lidless cold plate assembly 272 may also include seal fasteners 234 to enable the manifold lid 236 to be fastened, around a first perimeter relative to the distribution channels 232B, to the distribution manifold 232. The lidless cold plate assembly 272 may also include load fasteners 274 to enable a predetermined loading between the manifold lid 236 and the distribution manifold 232 at a second perimeter that is further away from a center of the lidless cold plate assembly than the first perimeter.

FIG. 2E is an illustration of a lidless cold plate assembly 290 having a lidless cold plate, a distribution manifold, and a stiffener frame, in at least one embodiment. As illustrated, a system of a lidless cold plate assembly may include a lidless cold plate 252, a distribution manifold 232, and a stiffener frame 242. The lidless cold plate 252 may be configured for association with an underlying component. As illustrated in FIG. 2D, the lidless cold plate may have exposed heat removal microchannels. The distribution manifold 232 may be associated with central fasteners for fastening the distribution manifold 232 to the lidless cold plate 252. The stiffener frame 424 may be associated with perimeter fasteners for fastening the stiffener frame to the lidless cold plate 252. Such a system incorporates structural integrity for a lidless cold plate assembly.

FIG. 2F is an illustration of aspects 295 associated with reduced deflection in a lidless cold plate assembly from using internal screw retention, described as central fasteners herein, in at least one embodiment. The central fasteners 232A may be a set of fasteners that may be provided in one center location to combat fluid pressure-based deformation. This can address internal fluid pressure deformation that may be caused when external forces on a cold plate retention are not balanced. The lidless cold plate assembly 290 herein may be subject to pressures of 100 psi of internal fluid pressure and 30 psi of external compression forces. The central fasteners 232A that may be between the distribution manifold and the lidless cold plate can link to distribution channels of the distribution manifold 232 to reduce deflection that may otherwise occur in a lidless cold plate, by more than 90%. Such reduction can improve thermal joint quality and reduction in silicon stresses.

When external forces of cold plate retention are not balanced against internal fluid, pressure deformation can result. A first deflection area 296A of pressure deformation indicates a center-focused deflection, in an example of a cold plate assembly without central fasteners 232A. This can result in stress on silicon components and integrity of the thermal interface bond. However, the addition of the screw retention links or central fasteners 232A within the heat removal microchannels of the lidless cold plate 252 and within the distribution channels of the distribution manifold 232 results in reduce deflection by about 96%, as indicated in the two reduced deflection areas 296B at the center of a lidless cold plate assembly. The reduced deflection areas 296B can dramatically improve thermal joint quality and silicon stress associated with one or more of a lidless cold plate or an underlying component.

FIG. 3A is an illustration of sealing and guidance aspects 300 of a lidless cold plate assembly, in at least one embodiment. FIG. 3A provides cross-section of a lidless cold plate assembly 272 that is a cross-section across a manifold lid, a manifold port plate, a distribution manifold, a bypass seal, a stiffener frame, a lidless cold plate, and an underlying component. The guidance aspect includes features in the distribution manifold 232 that form the distribution channels 232B by a fin array 302. Media from the fluid or media inlet 238A passes into the distribution channels 232B through ports 276B of the manifold port plate 276. Each of the distribution channels 232B may include a port 304 to guide media from the distribution channels 232B to the underlying heat removal microchannels 244 of the lidless cold plate 252. The heat removal microchannels 244 may be perpendicular to the distribution channels 232B. The heat removal microchannels 244 also support rotation of the media so that the media can exit the heat removal microchannels 244 to the distribution channels 232B and through different ports that are exit ports of the provided ports 276B of the manifold port plate 276. Then, the media exits the lidless cold plate assembly 272 via the exit port 238B. FIG. 3A also illustrates sections of the different O-ring seals 278, 280, 284 of the lidless cold plate assembly.

FIG. 3B is a detailed illustration of certain guidance aspects 350 of a lidless cold plate assembly, in at least one embodiment. The guidance aspects 350 are illustrated from a cut-section along an axis illustrated and marked in FIG. 3A. The guidance aspects 350 may include the heat removal microchannels 244 that extend perpendicularly to the distribution channels 232B. FIG. 3B also provides detailed illustration of a profile or feature that may include the central apertures 232C of the distribution manifold 232 and the cold plate central apertures 246 of the lidless cold plate 252, which may be predetermined, as to location and dimensions, based in part on a pressure of fluid to be handled in the lidless cold plate assembly 272 and an anti-deflection measure, in the heat removal microchannels 244, to be achieved under the pressure of the fluid. The central apertures 232C of the distribution manifold 232 may accept the central fasteners 232A as threaded or pass-through and to couple, via seal apertures 282A of a bypass seal 282, to the cold plate central apertures 246 of the lidless cold plate 252. At least such central fasteners 232A may be screw to counter fluid pressure deformation in the lidless cold plate assembly.

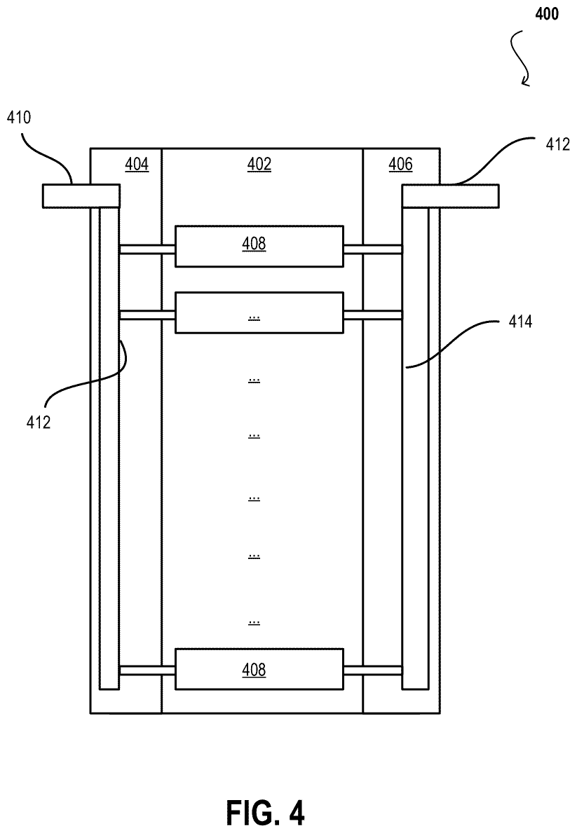

FIG. 4 illustrates rack aspects 400 in a system subject to a lidless cold plate assembly, according to at least one embodiment. A rack 402 has brackets 404, 406, to enable hanging of one or more cooling loop components within the rack 402. In at least one embodiment, rack manifolds 412, 414 may be provided to guide media from row manifolds to the computer modules 408 with the rack 402. The rack manifolds 412 may pass media of a secondary cooling loop from the row manifolds through conduit 410, through the server trays or boxes 408, out of the egress row manifold 414, and back into the row manifold via the egress conduit 412. The lidless cold plate assemblies herein may be used in any of the illustrated server tray or box forming the computer modules 408 and may also benefit from additional local distribution units if there is a need to increase pressure of media flow at any level of a rack.

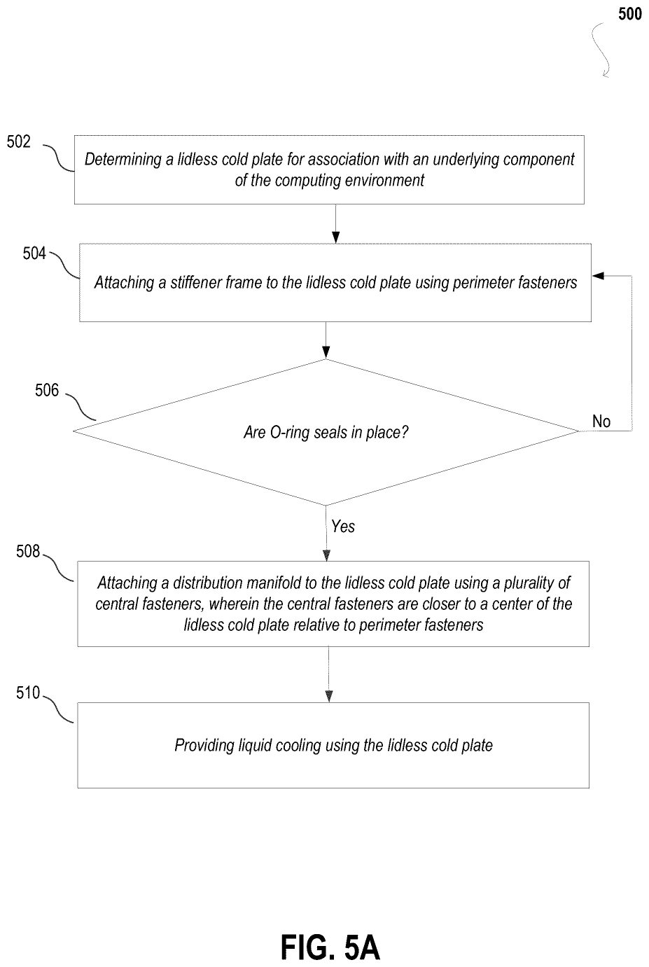

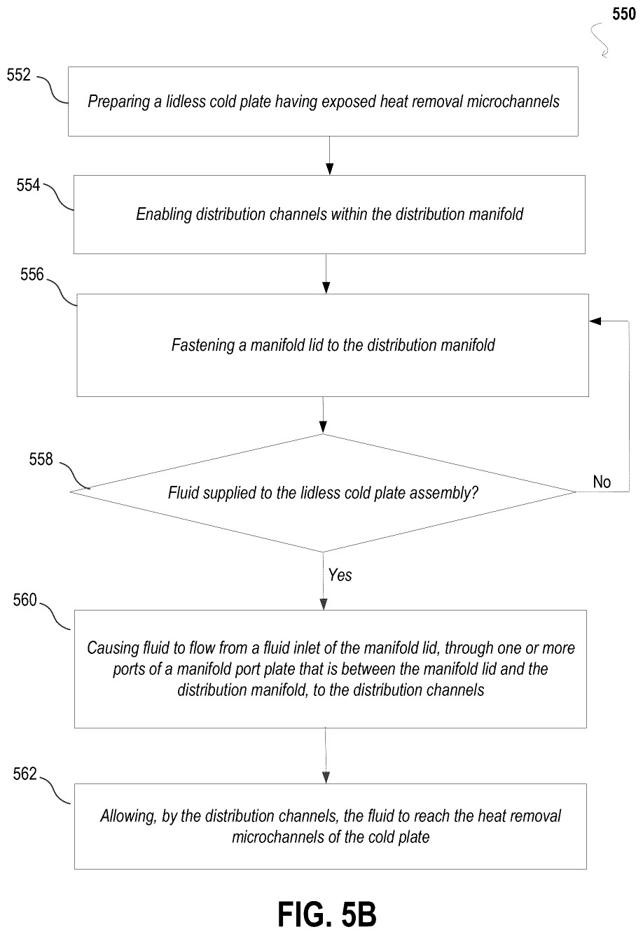

FIG. 5A illustrates a process flow or method 500 for a system having at least one lidless cold plate assembly, in at least one embodiment. The method 500 may include determining 502 a lidless cold plate for association with an underlying component of the computing environment. This may be performed based in part on a pressure of a fluid to be handled in the lidless cold plate assembly, a stiffening measurement determined for the lidless cold plate assembly, and an anti-deflection measure, in the heat removal microchannels, to be achieved under the pressure of the fluid. The method 500 may include attaching 504 a stiffener frame to the lidless cold plate using perimeter fasteners.

The method 500 may include determining or verifying 506 that one or more O-ring seals associated with the attaching 504 step is properly performed. For instance, leak tests may be performed as part of the determining or verifying step 506 herein. The method 500 may include attaching 508 a distribution manifold to the lidless cold plate using a plurality of central fasteners. Further, the method 500 ensures that the central fasteners are closer to a center of the lidless cold plate relative to perimeter fasteners as part of one or more of the steps 502-508 herein. The method 500 may include providing 510 liquid cooling using the lidless cold plate in operation with the underlying component subject to computing operations.

The method 500 may include a further step or sub-step where the lidless cold plate has exposed heat removal microchannels and where a bypass seal can be used to seal between the lidless cold plate and the distribution manifold overlying the lidless cold plate. Further, method 500 may include a further step or sub-step for using, in part, the central fasteners to hold the bypass seal in place to provide the seal and to maintain fluid for cooling within the heat removal microchannels.

The method 500 may include a further step or sub-step of using a first O-ring seal for a first seal between the stiffener frame and the lidless cold plate, and of using a second O-ring seal for a second seal between a distribution manifold and a manifold lid that is overlying distribution channels of the distribution manifold.

FIG. 5B illustrates yet another process flow or method 550 for a system having at least one lidless cold plate assembly, in at least one embodiment. The method 550 of FIG. 5B may be used alone or in combination with the method 500 of FIG. 5A by detailing further steps or sub-steps for the method 500 in FIG. 5A. The method 550 may include preparing 552 a lidless cold plate having exposed heat removal microchannels. The step of preparing 552 may include determining, machining, and designing the lidless cold plate to suit an application within an underlying component. The method 550 may include enabling 554 distribution channels within the distribution manifold. The step of enabling 554 such distribution channels may include a preparing step in the manner of the preparing step 552 of the lidless cold plate and may also include sub-steps or steps for determining, machining, and designing of the distribution manifold to include the distribution channels. In one example, the distribution manifold has to align with the lidless cold plate and, therefore, it is apparent that one or more steps in the methods 500, 550 of FIGS. 5A, 5B may be performed in a different order or by interchanging or repeating of steps within the generally provided method steps.

The method 550 may include fastening 556 a manifold lid to the distribution manifold. This or any of such steps in the methods herein may include verification or determining that proper O-ring seals are put in place before one or more fastening or attaching steps are performed. The method 550 may include determining or verifying 558 that fluid supplied to the lidless cold plate assembly. The lidless cold plate assembly incorporating at least steps 552-554 supports causing 560 fluid to flow from a fluid inlet of the manifold lid, through one or more ports of a manifold port plate that is between the manifold lid and the distribution manifold, to the distribution channels. The lidless cold plate assembly incorporating at least steps 552-554 also supports allowing 562, by the distribution channels, the fluid to reach the heat removal microchannels of the lidless cold plate.

The method 550 may include enabling, using seal fasteners, the manifold lid to be fastened to the distribution manifold at locations that are around a first perimeter in relation to the distribution channels. This enabling step may be based in part on one or more preparing or enabling steps 552, 554 of the method 550 herein. The method 500 may also include enabling, using load fasteners, a predetermined loading between the manifold lid and the distribution manifold and at a second perimeter that is further away from a center of the lidless cold plate assembly than the first perimeter.

The method 550 may be such that the central fasteners are provided from above the lidless cold plate assembly and the perimeter fasteners are provided from below the lidless cold plate assembly. Further, the method 500 may be such that a first profile or feature associated with one or more of a first location of the central fasteners or a first loading on the central fasteners may be predetermined based in part on a pressure of a fluid to be handled in the lidless cold plate assembly and one or more of an anti-deflection measure or a stiffening measure, in the heat removal microchannels, to be achieved under the pressure of the fluid. The method 500 may also be so that a second profile or feature may be associated with one or more of a second location of the perimeter fasteners, a second loading on the perimeter fasteners, or a first dimension of the stiffener frame that is predetermined based in part on a second dimension of the underlying component, an anti-deflection measure, or a stiffening measure, in the heat removal microchannels, to be achieved under the pressure of the fluid to be handled in the lidless cold plate assembly.

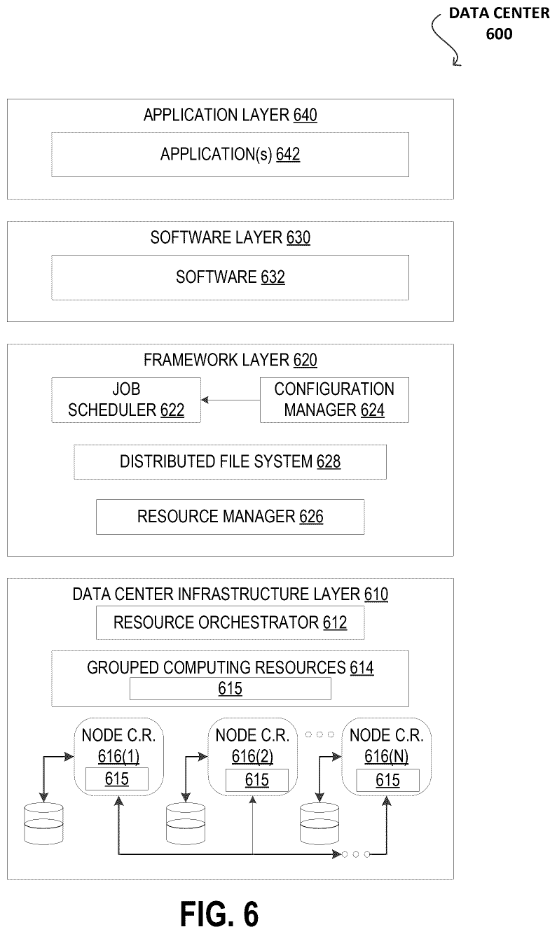

FIG. 6 illustrates an example datacenter 600, in which at least one embodiment from FIGS. 2A-5B may be used. For instance, the example datacenter 600 may be used to support one or more of the preparing or enabling steps to be used to generate or provide a lidless cold plate assembly for at least one underlying component of the example datacenter 600. However, the datacenter 600 may also include computer modules subject to a lidless cold plate assembly having a distribution manifold with central fasteners and a stiffener frame with perimeter fasteners, in at least one embodiment, as described with respect to FIGS. 1-5B herein.

In at least one embodiment, datacenter 600 includes a datacenter infrastructure layer 610, a framework layer 620, a software layer 630, and an application layer 640. In at least one embodiment, such as described in respect to FIGS. 1-5B, features of the lidless cold plate assembly may be performed inside or in collaboration with the example datacenter 600. Also, features to generate or provide a lidless cold plate assembly for at least one underlying component may be performed inside or in collaboration with the example datacenter 600. In at least one embodiment, the infrastructure layer 610, the framework layer 620, the software layer 630, and the application layer 640 may be partly or fully provided via computing components on server trays located in racks 110 of the datacenter 100. This enables cooling systems of the present disclosure to direct cooling to certain ones of the computing features in an efficient and effective manner. Further, aspects of the datacenter, including the datacenter infrastructure layer 610, the framework layer 620, the software layer 630, and the application layer 640 may be used to support selection or design for a lidless cold plate assembly as herein discussed with at least reference to FIGS. 1-5B above. As such, the discussion in reference to FIG. 6 may be understood to apply to the hardware and software features required to enable or support provision of a lidless cold plate, for instance.

In at least one embodiment, as in FIG. 6, datacenter infrastructure layer 610 may include a resource orchestrator 612, grouped computing resources 614, and node computing resources (“node C.R.s”) 616(1)-616(N), where “N” represents any whole, positive integer. In at least one embodiment, node C.R.s 616(1)-616(N) may include, but are not limited to, any number of central processing units (“CPUs”) or other processors (including accelerators, field programmable gate arrays (FPGAs), graphics processors, etc.), memory devices (such as dynamic read-only memory), storage devices (such as solid state or disk drives), network input/output (“NW I/O”) devices, network switches, virtual machines (“VMs”), power modules, and cooling modules, etc. In at least one embodiment, one or more node C.R.s from among node C.R.s 616(1)-616(N) may be a server having one or more of above-mentioned computing resources.

In at least one embodiment, grouped computing resources 614 may include separate groupings of node C.R.s housed within one or more racks (not shown), or many racks housed in datacenters at various geographical locations (also not shown). Separate groupings of node C.R.s within grouped computing resources 614 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 612 may configure or otherwise control one or more node C.R.s 616(1)-616(N) and/or grouped computing resources 614. In at least one embodiment, resource orchestrator 612 may include a software design infrastructure (“SDI”) management entity for datacenter 600. In at least one embodiment, resource orchestrator may include hardware, software or some combination thereof.

In at least one embodiment, as shown in FIG. 6, framework layer 620 includes a job scheduler 622, a configuration manager 624, a resource manager 626 and a distributed file system 628. In at least one embodiment, framework layer 620 may include a framework to support software 632 of software layer 630 and/or one or more application(s) 642 of application layer 640. In at least one embodiment, software 632 or application(s) 642 may respectively include web-based service software or applications, such as those provided by Amazon Web Services, Google Cloud and Microsoft Azure. In at least one embodiment, framework layer 620 may be, but is not limited to, a type of free and open-source software web application framework such as Apache Spark^{TM} (hereinafter “Spark”) that may utilize distributed file system 628 for large-scale data processing (such as “big data”). In at least one embodiment, job scheduler 622 may include a Spark driver to facilitate scheduling of workloads supported by various layers of datacenter 600. In at least one embodiment, configuration manager 624 may be capable of configuring different layers such as software layer 630 and framework layer 620 including Spark and distributed file system 628 for supporting large-scale data processing. In at least one embodiment, resource manager 626 may be capable of managing clustered or grouped computing resources mapped to or allocated for support of distributed file system 628 and job scheduler 622. In at least one embodiment, clustered or grouped computing resources may include grouped computing resource 614 at datacenter infrastructure layer 610. In at least one embodiment, resource manager 626 may coordinate with resource orchestrator 612 to manage these mapped or allocated computing resources.

In at least one embodiment, software 632 included in software layer 630 may include software used by at least portions of node C.R.s 616(1)-616(N), grouped computing resources 614, and/or distributed file system 628 of framework layer 620. One or more types of software may include, but are not limited to, Internet web page search software, e-mail virus scan software, database software, and streaming video content software.

In at least one embodiment, application(s) 642 included in application layer 640 may include one or more types of applications used by at least portions of node C.R.s 616(1)-616(N), grouped computing resources 614, and/or distributed file system 628 of framework layer 620. One or more types of applications may include, but are not limited to, any number of a genomics application, a cognitive compute, and a machine learning application, including training or inferencing software, machine learning framework software (such as PyTorch, TensorFlow, Caffe, etc.) or other machine learning applications used in conjunction with one or more embodiments.

In at least one embodiment, any of configuration manager 624, resource manager 626, and resource orchestrator 612 may implement any number and type of self-modifying actions based on any amount and type of data acquired in any technically feasible fashion. In at least one embodiment, self-modifying actions may relieve a datacenter operator of datacenter 600 from making possibly bad configuration decisions and possibly avoiding underutilized and/or poor performing portions of a datacenter.

In at least one embodiment, datacenter 600 may include tools, services, software or other resources to train one or more machine learning models or predict or infer information using one or more machine learning models according to one or more embodiments described herein. In at least one embodiment, in at least one embodiment, a machine learning model may be trained by calculating weight parameters according to a neural network architecture using software and computing resources described above with respect to datacenter 600. In at least one embodiment, trained machine learning models corresponding to one or more neural networks may be used to infer or predict information using resources described above with respect to datacenter 600 by using weight parameters calculated through one or more training techniques described herein. Deep learning may be advanced using any appropriate learning network and the computing capabilities of the datacenter 600. As such, a deep neural network (DNN), a recurrent neural network (RNN) or a convolutional neural network (CNN) may be supported either simultaneously or concurrently using the hardware in the datacenter. Once a network is trained and successfully evaluated to recognize data within a subset or a slice, for instance, the trained network can provide similar representative data for using with the collected data.

In at least one embodiment, datacenter 600 may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as pressure, flow rates, temperature, and location information, or other artificial intelligence services.

Inference and/or training logic 615 may be used to perform inferencing and/or training operations associated with one or more embodiments. In at least one embodiment, inference and/or training logic 615 may be used in system FIG. 6 for inferencing or predicting operations based, at least in part, on weight parameters calculated using neural network training operations, neural network functions and/or architectures, or neural network use cases described herein. In at least one embodiment, inference and/or training logic 615 may include, without limitation, hardware logic in which computational resources are dedicated or otherwise exclusively used in conjunction with weight values or other information corresponding to one or more layers of neurons within a neural network. In at least one embodiment, inference and/or training logic 615 may be used in conjunction with an application-specific integrated circuit (ASIC), such as Tensorflow® Processing Unit from Google, an inference processing unit (IPU) from Graphcore™, or a Nervana® (such as “Lake Crest”) processor from Intel Corp.

In at least one embodiment, inference and/or training logic 615 may be used in conjunction with central processing unit (CPU) hardware, graphics processing unit (GPU) hardware or other hardware, such as field programmable gate arrays (FPGAs). In at least one embodiment, inference and/or training logic 615 includes, without limitation, code and/or data storage modules which may be used to store code (such as graph code), weight values and/or other information, including bias values, gradient information, momentum values, and/or other parameter or hyperparameter information. In at least one embodiment, each of the code and/or data storage modules is associated with a dedicated computational resource. In at least one embodiment, the dedicated computational resource includes computational hardware that further include one or more ALUs that perform mathematical functions, such as linear algebraic functions, only on information stored in code and/or data storage modules, and results from which are stored in an activation storage module of the inference and/or training logic 615.

Therefore, the datacenter 600 herein, supports a silicon package that may include a component that may be a silicon component to perform a workload and that may be associated with a cold plate assembly. The silicon package can be part of the component or can include a computing feature of the component described throughout herein in FIGS. 1-5B. The cold plate assembly may include a lidless cold plate, a distribution manifold with central fasteners to the lidless cold plate, and a stiffener frame with perimeter fasteners to the lidless cold plate. The central fasteners in the silicon package may be located closer to a center of the lidless cold plate assembly relative to the perimeter fasteners.

In addition, the datacenter 600 herein may include one or more racks having one or more server trays. There may be one or more components in the one or more racks to perform at least part of a workload in the datacenter. The one or more components may be associated with a cold plate assembly and may include a lidless cold plate, a distribution manifold with central fasteners to the lidless cold plate, and a stiffener frame with perimeter fasteners to the lidless cold plate. The central fasteners may be located closer to a center of the lidless cold plate assembly relative to the perimeter fasteners.

In the following description, numerous specific details are set forth to provide a more thorough understanding of at least one embodiment. However, it will be apparent to one skilled in the art that the inventive concepts may be practiced without one or more of these specific details.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on. ”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system of a lidless cold plate assembly, comprising:
a lidless cold plate configured for association with an underlying component;
a distribution manifold with central fasteners to the lidless cold plate; and
a stiffener frame with perimeter fasteners to the lidless cold plate.

2. The system of claim 1, wherein the central fasteners are closer to a center of the lidless cold plate assembly relative to the perimeter fasteners.

3. The system of claim 1, wherein the lidless cold plate comprises exposed heat removal microchannels, and the system further comprising:
a bypass seal between the lidless cold plate and the distribution manifold overlying the lidless cold plate, the bypass seal to be held in place, in part by the central fasteners and to maintain fluid for cooling within the heat removal microchannels.

4. The system of claim 1, further comprising:
a first O-ring seal between the stiffener frame and the lidless cold plate; and
a second O-ring seal between a distribution manifold and a manifold lid that is overlying distribution channels of the distribution manifold.

5. The system of claim 1, wherein the distribution manifold comprises distribution channels, and the system further comprising:
a manifold lid fastened to the distribution manifold; and
a manifold port plate between the manifold lid and the distribution manifold to guide fluid from a fluid inlet of the manifold lid, through one or more ports of the manifold port plate, to the distribution channels, wherein the distribution channels allow the fluid to reach the heat removal microchannels of the lidless cold plate.

6. The system of claim 5, further comprising:
seal fasteners to enable the manifold lid to be fastened to the distribution manifold at locations that are around a first perimeter in relation to the distribution channels; and
load fasteners to enable a predetermined loading between the manifold lid and the distribution manifold at a second perimeter that is further away from a center of the lidless cold plate assembly than the first perimeter.

7. The system of claim 1, wherein the central fasteners are provided from above the lidless cold plate assembly and the perimeter fasteners are provided from below the lidless cold plate assembly.

8. The system of claim 1, wherein a profile or feature associated with one or more of a location of the central fasteners or a loading on the central fasteners is predetermined based in part on a pressure of a fluid to be handled in the lidless cold plate assembly and one or more of an anti-deflection measure or a stiffening measure, in the heat removal microchannels, to be achieved under the pressure of the fluid.

9. The system of claim 1, wherein a profile or feature is associated with one or more of a location of the perimeter fasteners, a loading on the perimeter fasteners, or a first dimension of the stiffener frame that is predetermined based in part on a second dimension of the underlying component, an anti-deflection measure, or a stiffening measure, in the heat removal microchannels, to be achieved under a pressure of a fluid to be handled in the lidless cold plate assembly.

10. A lidless cold plate assembly comprising a lidless cold plate, a distribution manifold with central fasteners to the lidless cold plate, and a stiffener frame with perimeter fasteners to the lidless cold plate, wherein the central fasteners are closer to a center of the lidless cold plate assembly relative to the perimeter fasteners.

11. The lidless cold plate assembly of claim 10, further comprising:
a plurality of exposed heat removal microchannels; and
a bypass seal between the lidless cold plate and the distribution manifold overlying the lidless cold plate, the bypass seal to be held in place, in part by the central fasteners and to maintain fluid for cooling within the plurality of heat removal microchannels.

12. The lidless cold plate assembly of claim 10, further comprising:
a first O-ring seal between the stiffener frame and the lidless cold plate; and
a second O-ring seal between a distribution manifold and a manifold lid that is overlying distribution channels of the distribution manifold.

13. The lidless cold plate assembly of claim 10, further comprising:
a plurality of distribution channels in the distribution manifold;
a manifold lid fastened to the distribution manifold; and
a manifold port plate between the manifold lid and the distribution manifold to guide fluid from a fluid inlet of the manifold lid, through one or more ports of the manifold port plate, and to the plurality of distribution channels, wherein the distribution channels allow the fluid to reach the heat removal microchannels of the lidless cold plate.

14. The lidless cold plate assembly of claim 13, further comprising:
a plurality of seal fasteners to enable the manifold lid to be fastened, around a first perimeter relative to the distribution channels, to the distribution manifold; and
a plurality of load fasteners to enable a predetermined loading between the manifold lid and the distribution manifold at a second perimeter that is further away from the center of the lidless cold plate assembly than the first perimeter.

15. A method for cooling in a computing environment, the method comprising:
determining a lidless cold plate for association with an underlying component of the computing environment;
attaching a stiffener frame to the lidless cold plate using a plurality of perimeter fasteners; and
attaching a distribution manifold to the lidless cold plate using a plurality of central fasteners, wherein the central fasteners are closer to a center of the lidless cold plate relative to the perimeter fasteners.

16. The method of claim 15, wherein the lidless cold plate comprises exposed heat removal microchannels, and the method further comprising:
using a bypass seal to seal between the lidless cold plate and the distribution manifold overlying the lidless cold plate; and
using, in part, the central fasteners to hold the bypass seal in place to provide the seal and to maintain fluid for cooling within the heat removal microchannels.

17. The method of claim 15, further comprising:
using a first O-ring seal for a first seal between the stiffener frame and the lidless cold plate; and
using a second O-ring seal for a second seal between a distribution manifold and a manifold lid that is overlying distribution channels of the distribution manifold.

18. The method of claim 15, further comprising:
enabling a plurality of distribution channels within the distribution manifold;
fastening a manifold lid to the distribution manifold; and
causing fluid from a fluid inlet of the manifold lid, through one or more ports of a manifold port plate that is between the manifold lid and the distribution manifold, to the plurality of distribution channels, wherein the plurality of distribution channels allow the fluid to reach the heat removal microchannels of the flexible cold plate.

19. The method of claim 18, further comprising:
enabling, using seal fasteners, the manifold lid to be fastened to the distribution manifold at locations that are around a first perimeter in relation to the distribution channels; and
enabling, using load fasteners, a predetermined loading between the manifold lid and the distribution manifold and at a second perimeter that is further away from the center of the lidless cold plate assembly than the first perimeter.

20. The method of claim 15, wherein the central fasteners are provided from above the lidless cold plate assembly and the perimeter fasteners are provided from below the lidless cold plate assembly.

21. The method of claim 15, wherein a first profile or feature associated with one or more of a first location of the central fasteners or a first loading on the central fasteners is predetermined based in part on a pressure of a fluid to be handled in the lidless cold plate assembly and one or more of an anti-deflection measure or a stiffening measure, in the heat removal microchannels, to be achieved under the pressure of the fluid; or wherein a second profile or feature is associated with one or more of a second location of the perimeter fasteners, a second loading on the perimeter fasteners, or a first dimension of the stiffener frame that is predetermined based in part on a second dimension of the underlying component, an anti-deflection measure, or a stiffening measure, in the heat removal microchannels, to be achieved under the pressure of the fluid to be handled in the lidless cold plate assembly.

22. A silicon package comprising a component to perform a workload and associated with a cold plate assembly, the cold plate assembly comprising a lidless cold plate, a distribution manifold with central fasteners to the lidless cold plate, and a stiffener frame with perimeter fasteners to the lidless cold plate, wherein the central fasteners are closer to a center of the lidless cold plate assembly relative to the perimeter fasteners.

23. A datacenter comprising:
one or more racks comprising one or more server trays;
one or more components in the one or more racks, the one or more components to perform at least part of a workload in the datacenter; and
a cold plate assembly associated with the one or more components, the cold plate assembly comprising a lidless cold plate, a distribution manifold with central fasteners to the lidless cold plate, and a stiffener frame with perimeter fasteners to the lidless cold plate, wherein the central fasteners are closer to a center of the lidless cold plate assembly relative to the perimeter fasteners.
